(19) United States
(12) Patent Application Publication
(10) Pub. No.: US 2008/0085576 A1
(43) Pub. Date: Apr. 10, 2008

(54) Manufacturing Method for Semiconductor Device

(76) Inventor: HAN CHOON LEE, Songpa-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/780,002

(22) Filed: Jul. 19, 2007

(30) Foreign Application Priority Data
Jul. 21, 2006 (KR) 10-2006-0068530

(51) Int. Cl. H01L 21/336

(52) U.S. Cl. 438/197; 257/E21.409

(57) ABSTRACT

Disclosed is a manufacturing method for a semiconductor device capable of uniformly and stably silicidating an entire gate. The method includes: forming a gate oxide layer and a polysilicon pattern on a substrate; forming a spacer on a sidewall of the gate oxide layer and the polysilicon pattern; forming a source and a drain in a substrate area exposed at a side of the spacer; forming a first metal layer on the substrate and then performing a heat treatment with respect to the first metal layer, thereby forming a salicide; forming a nitride layer and an interlayer dielectric layer on the substrate including the salicide and the spacer; removing the salicide on the polysilicon pattern; and forming a second metal layer on the substrate and then performing a heat treatment with the second metal layer such that the polysilicon pattern is silicided, thereby completing a gate.

### CROSS-REFERENCE TO RELATED APPLICATION

The present application claims the benefit under 35 U.S.C. §119 of Korean Patent Application No. 10-2006-0068530, filed Jul. 21, 2006, which is hereby incorporated by reference in its entirety.

### BACKGROUND

As semiconductor devices have become highly integrated, the channel length of a transistor constituting the semiconductor device has decreased to a few tens of nanometers or less. As the channel length of the transistor decreases, depletion of polysilicon occurs. Therefore, the equivalent oxide thickness (EOT) of a gate oxide layer may be increased.

A metal gate is used to reduce the depletion of polysilicon. However, when the metal gate is applied to a CMOS (Complementary Metal Oxide Semiconductor) transistor, different metals must be used in n-channel and p-channel MOS areas, complicating the process. Thus, a fully silicided (FUSI) gate structure has been recently suggested, in which a metal is deposited on polysilicon, and a metal silicide is then formed through a subsequent heat treatment.

However, when a FUSI gate is formed through only a heat treatment, an entire gate is not silicidated due to a salicide (self-aligned silicide) for source and drain areas previously formed on a poly-gate.

### BRIEF SUMMARY

Embodiments of the present invention provide a method capable of uniformly and stably siliciding an entire gate.

According to an aspect of an embodiment of the present invention, there is provided a method for manufacturing a semiconductor device, which includes: forming a gate oxide layer and a polysilicon pattern on a substrate; forming a spacer on a sidewall of the gate oxide layer and the polysilicon pattern; forming a source and a drain in a substrate area exposed at a side of the spacer; forming a first metal layer on the substrate and then performing a heat treatment with respect to the first metal layer, thereby forming a salicide; forming a nitride layer and an interlayer dielectric layer on the salicide and the spacer; removing the salicide on the polysilicon pattern; and forming a second metal layer on the substrate and then performing a heat treatment with the second metal layer such that the polysilicon pattern is silicided, thereby completing a gate.

### BRIEF DESCRIPTION OF THE DRAWINGS

FIG. 1 is a cross-sectional view showing a configuration of a semiconductor device manufactured through a manufacturing method according to an embodiment of the present invention.

FIGS. 2-6 are views for illustrating a method of manufacturing a semiconductor device according to an embodiment of the present invention.

FIG. 2 is a cross-sectional view showing a configuration of a semiconductor device after forming isolation areas in the manufacturing method for the semiconductor device according to an embodiment;

FIG. 3 is a cross-sectional view showing a configuration of the semiconductor device after forming a low-density doping area in the manufacturing method for the semiconductor device according to an embodiment;

FIG. 4 is a cross-sectional view showing a configuration of the semiconductor device after forming a source and a drain in the manufacturing method for the semiconductor device according to an embodiment;

FIG. 5 is a cross-sectional view showing a configuration of the semiconductor device after forming a salicide (self-aligned silicide) in the manufacturing method for the semiconductor device according to an embodiment; and

FIG. 6 is a cross-sectional view showing a configuration of the semiconductor device after forming an interlayer dielectric layer in the manufacturing method for the semiconductor device according to an embodiment.

### DETAILED DESCRIPTION

Hereinafter, a manufacturing method for a semiconductor device according to embodiments of the present invention will be described in detail with reference to the accompanying drawings.

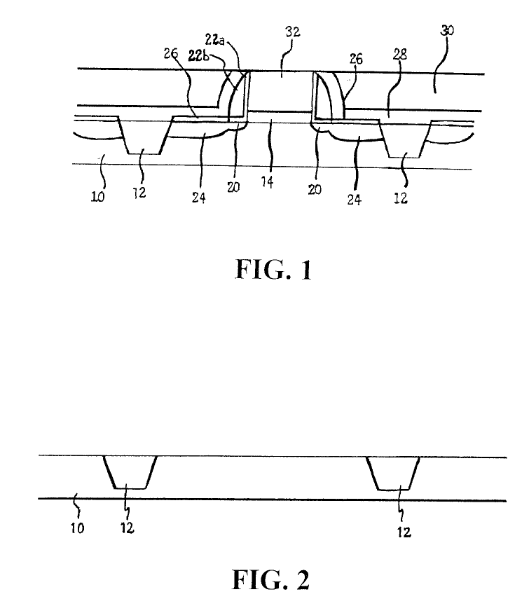

FIG. 1 is a cross-sectional view showing a configuration of a semiconductor device manufactured through a manufacturing method according to an embodiment of the present invention.

Referring to FIG. 1, a semiconductor device according to an embodiment can include source and drain regions 24 formed in a substrate 10 having isolation layers 12 defined therein and a channel area formed between the source and drain regions 24.

The source and drain regions 24 can include low-density areas 20 formed by implanting ions at a low concentration.

The source and drain 24 are doped with conductive impurity ions at a high density. The channel area is an intrinsic semiconductor area, and may be doped with ions for adjusting a threshold voltage (Vth).

A gate oxide layer 14 can be formed on the substrate 10 on the channel area, and a gate 32 can be formed on the gate oxide layer 14. A buffer layer 22a and a spacer 22b can be formed on a sidewall of the gate 32.

The spacer 22b can be a nitride such as SiN, and the gate 32 is formed of a silicide such as, for example, CoSi₂ or TiSi₂.

As described above, the low-density doping areas 20 doped with conductive impurity ions at a lower density than the source and drain regions 24 are formed in the substrate 10 below the spacer 22b.

A salicide 26 is formed on the exposed source and drain regions 24 in the substrate 10.

A nitride layer 28 and an interlayer dielectric layer 30 are formed on the source and drain regions 24 and on the sidewall of the spacer 22b such that the top surface of the gate 32 is exposed.

A manufacturing method of a semiconductor device having such a structure will be described with reference to FIGS. 2 to 6.

FIG. 2 is a side sectional view showing a configuration of a semiconductor device after forming isolation areas 12 in a manufacturing method for a semiconductor device according to an embodiment.

Referring to FIG. 2, isolation areas 12 are formed on the semiconductor substrate 10 through a LOCOS (local oxidation of silicon) or STI (shallow trench insulation) process. The LOCOS process is a process of forming an isolation area by allowing an oxide layer to be partially grown in predetermined area of a substrate, and the STI process is a process of forming an isolation area by forming a trench in a predetermined area of a substrate and then filling an insulating material in the predetermined area.

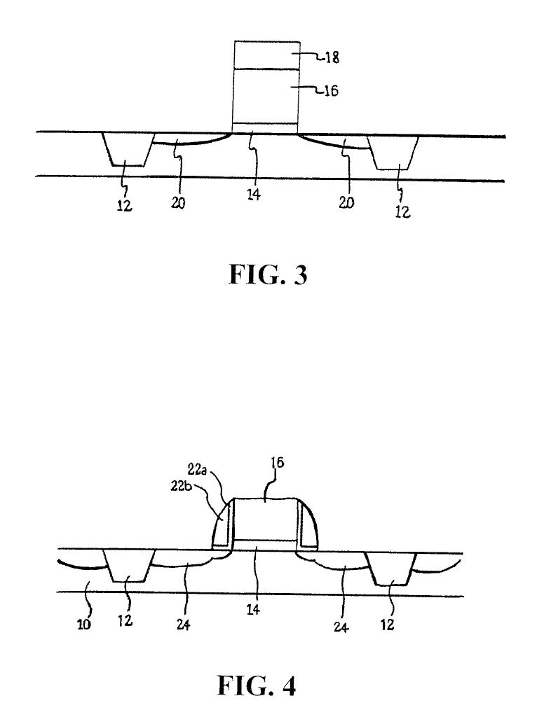

Referring to FIG. 3, the substrate 10 is oxidized to form a first oxide thereon. Sequentially, a polysilicon layer and a second oxide layer are stacked on the first oxide layer through a method such as a chemical vapor deposition (CVD). The polysilicon layer can be formed, for example, in a thickness of 1000 to 2000 Å.

Then, the first oxide layer, the polysilicon layer and the second oxide layer are sequentially patterned through a selective etching process, thereby forming a gate oxide layer 14 from the first oxide layer, a polysilicon pattern 16 from the polysilicon layer, and a hard mask 18 from the second oxide layer.

The hard mask 18 can be used to form more precise interconnections. The hard mask 18 may be omitted depending on a property of a photoresist used in the selective etching process.

Next, low-density doping areas 20 can be formed by implanting conductive impurity ions at a low concentration onto the substrate 10. In an embodiment, hard mask 18 can be removed before forming the low-density doping areas 20.

Referring to FIG. 4, oxide and nitride layers can be formed and then etched back to form a buffer layer 22a and a spacer 22b on a sidewall of the polysilicon pattern 16. In some embodiments, a halo implant can be performed before forming the spacer 22b.

Subsequently, a source and a drain 24 can be formed by implanting conductive impurity ions at a high concentration onto the entire surface of the substrate 10.

At this time, the implanted ions can be an n-type or p-type impurity, e.g., As, P or B.

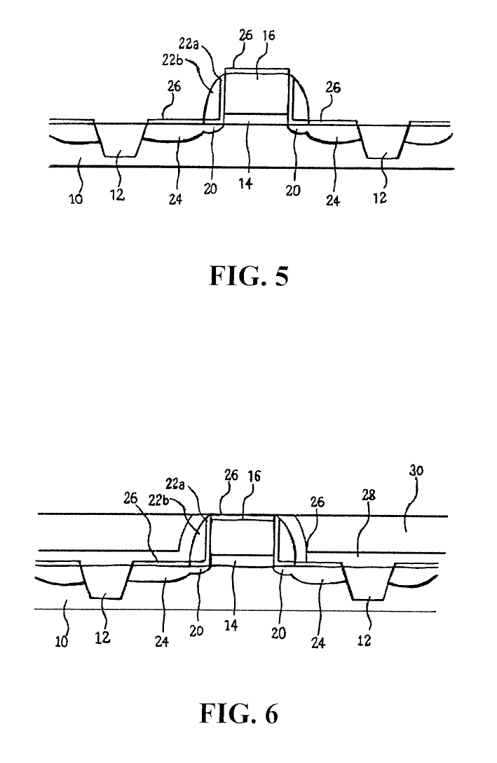

Referring to FIG. 5, a metal such as, for example, titanium (Ti), nickel (Ni) or cobalt (Co) can be deposited on the entire surface of the substrate 10 and then rapidly heat treated, thereby forming a salicide 26. At this time, the salicide 24 is formed on the top surface of the polysilicon pattern 16 that is not protected by the spacer 22b and on the source and drain regions 24.

Then, referring to FIG. 6, a nitride layer 28 is formed on the substrate 10, and an interlayer dielectric layer 30 is formed on the nitride layer 28. The interlayer dielectric layer 30 can be formed of an oxide such as TEOS.

Subsequently, a primary planarization process is performed through a CMP (chemical mechanical polishing) process until the salicide 26 on the polysilicon pattern 16 is exposed.

Then, the exposed salicide 26 is removed by performing a secondary planarization through, for example a tungsten (W) touch-up method.

The nitride layer 28 can serve as a base layer when the primary and secondary planarization processes are performed. The interlayer dielectric layer 30 on the polysilicon pattern 16 is removed through the primary planarization process. As the nitride layer 28 is exposed during the CMP process, the EDP (end point detector) signal is detected so that the first planarization process is finished.

Then, the salicide 26 on the polysilicon pattern 16 can be precisely removed through a W touch-up method.

Accordingly, the nitride layer 28 should be included in order to remove the salicide 26 from the polysilicon pattern 16 through the CMP process.

The tungsten (W) touch-up method refers to a planarization process that planarizes a metal layer, such as tungsten, through the CMP. In the embodiment, the metal layer is the salicide 26.

According to an embodiment, the selectivity between the salicide 26 and the interlayer dielectric layer is between 1:1 to 1:2. In addition, the CMP process can be performed under the process condition of an etching speed of 50 to 200 rpm and a pressure of 2 to 6 psi.

Through such a process, the semiconductor device as illustrated in FIG. 1 can be formed.

Referring to FIG. 1, a cobalt (Co) layer can be deposited on the interlayer dielectric layer 30, the nitride layer 28 and the polysilicon pattern 16, and a primary heat treatment can be performed with the Co layer such that the polysilicon pattern 16 is silicided.

By siliciding the polysilicon pattern 16 a gate 32 can be completed.

Since the volume of a metal layer including Co or the like is expanded two to three times in the first heat treatment, the metal layer can be formed to have a thickness at which the polysilicon pattern 16 can be sufficiently silicided. For example, when the polysilicon pattern 16 is formed in a thickness of 1500 Å, the Co metal layer is formed in a thickness of 600 to 800 Å. At this time, the gate 32 can be protruded higher than the spacer 22b. The protruded thickness of the gate can be, for example, 350 to 1350 Å.

After that, the Co metal layer that is not silicided is removed, and a secondary heat treatment can be performed to stabilize the silicide of the gate 32.

In another embodiment, the gate 32 can be formed of a Ni silicide instead of a Co silicide. For reference, a method of forming a Ni silicide can be the same as that of forming the salicide 26 of the source and drain 24 in FIG. 5.

As described above, according to embodiments of the present invention, since a salicide remaining on a gate is all removed, the gate can be prevented from being partially silicided due to the remaining salicide.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive. The above disclosed subject matter is to be considered illustrative, and not restrictive, and the appended claims are intended to cover all such modifications, enhancements, and other embodiments, which fall within the true spirit and scope of the present invention.

What is claimed is:

1. A method for manufacturing a semiconductor device, the method comprising:
forming a gate oxide layer and a polysilicon pattern on a substrate;
forming a spacer on a sidewall of the gate oxide layer and the polysilicon pattern;
forming a source and a drain in a substrate area exposed at a side of the spacer;
forming a first metal layer on the substrate and then performing a first heat treatment with respect to the first metal layer, thereby forming a salicide on the polysilicon pattern, the source and the drain;
forming a nitride layer and an interlayer dielectric layer on the substrate including the salicide and the spacer;
removing the salicide on the polysilicon pattern; and
forming a second metal layer on the substrate and then performing a second heat treatment with the second metal layer such that the polysilicon pattern is silicided.

2. The method according to claim 1, further comprising forming isolation areas on the substrate wherein the gate oxide layer and the polysilicon pattern are formed between the isolation areas.

3. The method according to claim 1, wherein forming the gate oxide layer and the polysilicon pattern comprises:
forming a first oxide layer on the substrate;
forming a polysilicon layer on the first oxide layer; and
patterning the first oxide layer and the polysilicon layer polysilicon polysilicon.

4. The method according to claim 3, further comprising:
forming a second oxide layer on the polysilicon layer after forming the polysilicon layer;
patterning the second oxide layer, wherein the patterned second oxide layer provides a hard mask for patterning the polysilicon layer; and
polysilicon polysilicon removing the hard mask.

5. The method according to claim 1, further comprising forming a low-density doping area by implanting ions into the substrate after forming the gate oxide layer and the polysilicon pattern.

6. The method according to claim 1, wherein forming the spacer comprises:
depositing a material for a buffer layer;
depositing a material for a spacer; and performing an etch back process to form a buffer layer on the sidewall of the gate oxide layer and the polysilicon pattern and a spacer pattern on the buffer layer.

7. The method according to claim 1, wherein forming a source and drain comprises implanting conductive impurity ions at a high concentration into the substrate area exposed at the side of the spacer.

8. The method according to claim 1, further comprising removing the first metal layer that is not salicided after performing the first heat treatment with respect to the first metal layer.

9. The method according to claim 1, further comprising removing the second metal layer that is not silicided after performing the second heat treatment with respect to the second metal layer.

10. The method according to claim 1, wherein removing the salicide on the polysilicon pattern comprises performing a chemical mechanical polishing (CMP) process.

11. The method according to claim 10, wherein the CMP process comprises a primary planarization process for removing the interlayer dielectric layer using the nitride layer as an end point and a secondary planarization process for removing the salicide, of a W touch-up method.

12. The method according to claim 10, wherein the CMP process is performed under conditions, where selectivity between the salicide and the interlayer dielectric layer is between 1:1 to 1:2, an etching speed is 50 to 200 rpm, and a pressure is 2 to 6 psi.

13. The method according claim 1, wherein the first metal layer comprises titanium (Ti), nickel (Ni) or cobalt (Co).

14. The method as claimed in according claim 1, wherein the second metal layer comprises nickel (Ni) or cobalt (Co).

15. The method according to claim 1, further comprising performing a third heat treatment to stabilize the silicided polysilicon pattern.
